(19) United States
(12) Patent Application Publication
(10) Pub. No.: US 2026/0068643 A1
(43) Pub. Date: Mar. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chih-Shiun CHOU, Hsinchu City (TW); Yi-Hsiang CHAO, New Taipei City (TW); Kan-Ju LIN, Kaohsiung City (TW); Chien CHANG, Hsinchu (TW); Yi-Ning TAI, Hsinchu (TW); Bo-Wei HSU, Taichung City (TW); Min-Zhen YANG, Hsinchu City (TW); Chiao-Fang HSU, Hsinchu (TW); Harry CHIEN, Chandler, AZ (US)

(21) Appl. No.: 19/003,055

(22) Filed: Dec. 27, 2024

Related U.S. Application Data
(60) Provisional application No. 63/690,553, filed on Sep. 4, 2024.

(51) Int. Cl. H01L 23/528; H01L 21/768; H01L 23/532

(52) U.S. Cl. CPC H01L 23/5283

(57) ABSTRACT

A pre-cleaning operation, using a metal-precursor, is performed to remove a metal-oxide layer from a top surface of a contact structure of a semiconductor device prior to forming a conductive structure of the semiconductor device on the contact structure. The use of the metal precursor as a pre-cleaning agent for the pre-cleaning operation enables native oxides to be fully removed (not just constituent parts such as oxygen) without causing the formation of pores in the top surface of the contact structure, which enables a low contact resistance to be achieved between the contact structure and the conductive structure.

### CROSS-REFERENCE TO RELATED APPLICATION

This patent application claims priority to U.S. Provisional Patent Application No. 63/690,553, filed on Sep. 4, 2024, and entitled “SEMICONDUCTOR DEVICE AND METHODS OF FORMATION.” The disclosure of the prior application is considered part of and is incorporated by reference into this patent application.

### BACKGROUND

An interconnect layer (sometimes referred to as a back end region or a back end of line (BEOL) region) is a region of semiconductor device that includes a plurality of layers of conductive structures that are arranged to carry signals and/or to provide power distribution throughout the semiconductor device. The plurality of layers of conductive structures may include various vertically-arranged layers of interconnect structures (e.g., vias) and layers of metallization structures (e.g., trenches, conductive lines, traces).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of a portion of an example semiconductor device described herein.

FIGS. 2A-2E are diagrams of an example implementation of forming the semiconductor device described herein.

FIGS. 3A-3H are diagrams of an example implementation of forming a source/drain interconnect structure described herein.

FIGS. 4A-4D are diagrams of example implementations of source/drain contact structures and source/drain interconnect structures for the semiconductor device described herein.

FIGS. 5A-5E are diagrams of example implementations of source/drain contact structures and source/drain interconnect structures for the semiconductor device described herein.

FIG. 6 is a flowchart of an example process associated with forming a semiconductor device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In interconnect layer of a semiconductor device may be formed above a device layer of the semiconductor device. The device layer may include a substrate layer of the semiconductor device and integrated circuit devices (e.g., transistors, capacitor, diodes, memory cells) in and/or on the semiconductor substrate. A layer of contact structures (referred to as source/drain contacts) may be included between the integrated circuit devices and the interconnect layer, and may electrically connect the integrated circuit devices to a bottom-most layer of conductive structures (referred to as source/drain interconnects and gate interconnects) in the interconnect layer.

To form a conductive structure of the interconnect layer on a contact structure, a recess may be formed through a dielectric layer to expose the top surface of the contact structure. The material of the conductive structure may then be deposited on the top surface of the contact structure so that the conductive structure and the contact structure are electrically coupled.

In some cases, a pre-cleaning operation may be performed on the top surface of the contact structure after forming the recess and prior to depositing the material of the contact structure. After forming the recess, a thin layer of metal-oxide material (referred to as “native oxides”) may form on the top surface of the contact structure due to exposure of the top surface to atmospheric oxygen and/or to oxygen used in semiconductor processes performed for the semiconductor device. This metal-oxide layer, if not removed, might otherwise increase the contact resistance between the contact structure and the conductive structure. However, the pre-cleaning operation may remove only the oxygen from the metal-oxide layer, resulting in formation of pores or other types of voids in the surface of the top surface of the contact structure, This porosity may increase the contact resistance between the contact structure and the conductive structure.

In some implementations described herein, a pre-cleaning operation, using a metal-precursor, is performed to remove a metal-oxide layer from a top surface of a contact structure of a semiconductor device prior to forming a conductive structure of the semiconductor device on the contact structure. The metal precursor may include a metal precursor of a metal material of the contact structure, a metal precursor of a metal material of the conductive structure, and/or another metal precursor. The metal precursor may be a halogen-based metal precursor that etches and removes both the oxygen and the metal constituent of the metal-oxide layer on the top surface of the contact structure, as opposed to removing only the oxygen constituent of the metal-oxides (which might otherwise result in formation of pores in the top surface of the contact structure that increase the contact resistance between the contact structure and the conductive structure). The resulting top surface of the contact structure after the pre-cleaning operation is smooth and substantially free of pores and other voids.

In this way, the use of the metal precursor as a pre-cleaning agent for the pre-cleaning operation enables native oxides to be fully removed (not just constituent parts such as oxygen) without causing the formation of pores in the top surface of the contact structure, which enables a low contact resistance to be achieved between the contact structure and the conductive structure. Moreover, the metal precursor may also etch some of the metal material of the top surface of the contact structure, resulting in the top surface becoming slightly recessed, which provides for a greater surface area across which the conductive structure contacts the contact structure. The increased surface area may further reduce the contact resistance between the conductive structure and the contact structure.

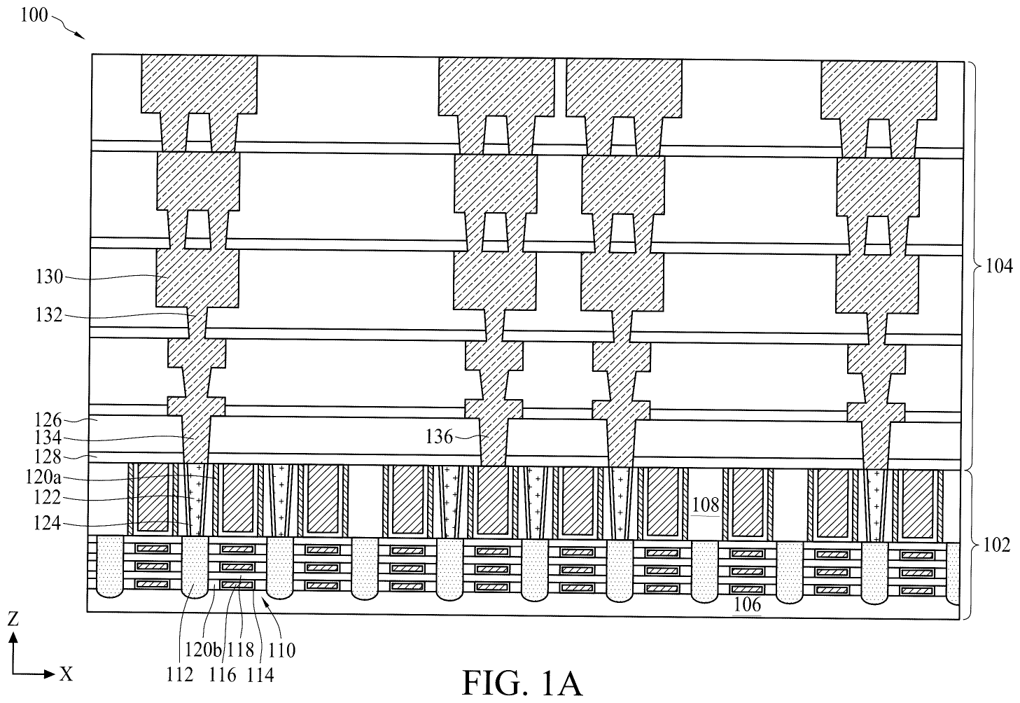

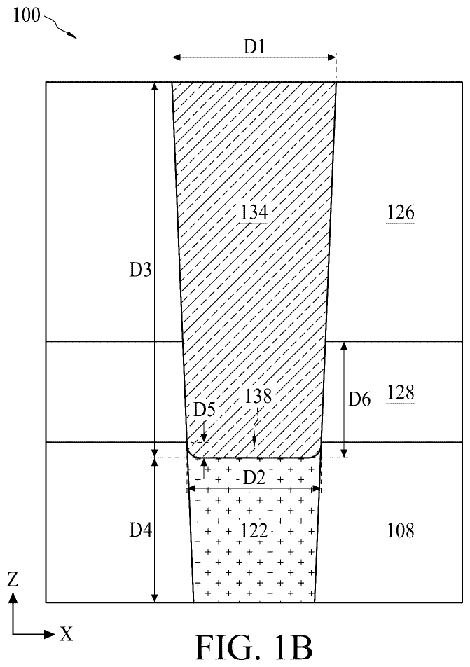

FIGS. 1A and 1B are diagrams of a portion of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1A, the semiconductor device 100 may include a device layer 102 and an interconnect layer 104 above the device layer 102 in a z-direction in the semiconductor device 100. The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

A dielectric layer 108 is included over the substrate layer 106. The dielectric layer 108 includes an interlayer dielectric (ILD) layer (e.g., an ILD0 layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 110 in the device layer 102. The dielectric layer 108 includes a silicon nitride (SiₓN_{y}), an oxide (e.g., a silicon oxide (SiOₓ) and/or another oxide material), and/or another type of dielectric material. The dielectric layer 108 may extend in the x-direction and/or in a y-direction in the semiconductor device 100.

The integrated circuit devices 110 may be included in and/or on the substrate layer 106, and/or in in the dielectric layer 108 in the device layer 102 of the semiconductor device 100. The integrated circuit devices 110 include transistors (e.g., planar transistors, fin field effect transistors (finFETs), gate all around (GAA) transistors), pixel sensors, capacitors, resistors, inductors, photodetectors, transceivers, transmitters, receivers, optical circuits, and/or other types of semiconductor devices.

An integrated circuit device 110 may include a plurality of source/drain regions 112 that are grown and/or otherwise formed on and/or around portions of the substrate layer 106. “Source/drain region(s)” may refer to a source or a drain, individually or collectively, dependent upon the context. The source/drain regions 112 may be formed by epitaxially growing doped semiconductor regions and/or by another semiconductor process. In some implementations, the source/drain regions 112 are formed in recessed portions in the substrate layer 106. The recessed portions may be formed by strained source/drain (SSD) etching of the substrate layer 106 and/or another type etching operation. In some implementations, the source/drain regions 112 are formed in recesses that are formed in an alternating stack of channel layers and sacrificial layers (e.g., silicon germanium (SiGe)) layers.

An integrated circuit device 110 may further include a gate dielectric layer 114 between a gate structure 116 and channel layers 118 of the integrated circuit device 110. The channel layers 118 may extend between the source/drain regions 112 of the integrated circuit device 110, and gate dielectric layer 114 and the gate structure 116 may wrap around two or more sides of the channel layers 118. In some implementations, the gate dielectric layer 114 and the gate structure 116 wrap around all four sides of the channel layers 118. In these implementations, the integrated circuit device 110 may be referred to as a nanostructure transistor such as a GAA transistor.

The channel layers 118 may include nanoscale layers of semiconductor material, such as silicon (Si), silicon germanium (SiGe), and/or doped silicon, among other examples. The channel layers 118 may be formed from silicon nanosheets that are formed as part of a nanosheet stack above the substrate layer 106.

In some implementations, the gate dielectric layer 114 includes a low dielectric constant (low-k) dielectric material such as silicon oxide (SiOₓ). In some implementations, the gate dielectric layer 114 includes a high dielectric constant (high-k) dielectric material such as hafnium oxide (HfOₓ).

The gate structure 116 may be located laterally between the source/drain regions 112. In some implementations, the gate structure 116 is formed of a polysilicon material. In these implementations, the polysilicon material may be doped with one or more types of dopants (e.g., p-type dopants, n-type dopants) to tune a work function of the gate structure 116.

In some implementations, the gate structure 116 is formed of one or more metal materials (e.g., tungsten (W), titanium (Ti), cobalt (Co), and/or another metal. In these implementations, the gate structure 116 may include one or more work function metal layers (e.g., p-type metal layers, n-type metal layers) for tuning the work function of the gate structure 116. The work function metal layer(s) may be included between the gate dielectric layer 114 and the gate structure 116.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 116 such that the work function is adjusted close to the valence band of the material of the channel layers 118.

An n-type work function metal layer may include one or more metal materials that tune or adjust the work function of the gate structure 116 near the conduction band of the material of the channel layers 118 of the semiconductor device 100. In some implementations, an n-type work function metal layer may include titanium aluminum (TiAl). In some implementations, an n-type work function metal layer includes titanium aluminum carbon (TiAlC). In some implementations, an n-type work function metal layer may include another aluminum-containing metal. In some implementations, another n-type metal material is included in an n-type work function metal layer.

Various spacers may be included in the integrated circuit devices 110. For example, sidewall spacers 120a may be included on the sidewalls of the gate structure 116 to provide electrical isolation for the gate structure 116, among other examples. In some implementations, the sidewall spacers 120a are in contact with the gate dielectric layer 114. In some implementations, the sidewall spacers 120a are in contact with the work function metal layer. The sidewall spacers 120a may include a silicon oxide (SiOₓ), a silicon nitride (SiₓN_{y}), a silicon oxycarbide (SiOC), a silicon oxycarbonitride (SiOCN), and/or another suitable material.

As another example, inner spacers 120b may be included laterally between the gate structure 116 and the source/drain regions 112 of an integrated circuit device 110. The inner spacer 120b may be included to reduce parasitic capacitance in the integrated circuit device 110 and to protect the source/drain regions 112 from being etched in a nanosheet release operation to remove sacrificial layers between the channel layers 118. The inner spacers 120b may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

The source/drain regions 112 are electrically coupled and/or physically coupled with source/drain contact structures 122. The source/drain contact structures 122 may include contact vias, contact plugs, and/or another type of contact structures that electrically connect the source/drain regions 112 of the integrated circuit devices 110 with the interconnect layer 104 of the semiconductor device 100. The source/drain contact structures 122 include cobalt (Co), ruthenium (Ru), tungsten (W), molybdenum (Mo), copper (Cu), and/or another electrically conductive material or metal material. One or more liner layers 124 may be included on sidewalls of the source/drain contact structures 122. The liner layer(s) 124 may include a barrier layer that is included to prevent or minimize diffusion of materials from the source/drain contact structures 122 to the surrounding dielectric layers, an adhesion layer or glue layer that is included to promote adhesion between the source/drain contact structures 122 and the surrounding dielectric layers, and/or another type of liner. Examples of materials for the liner layer(s) 124 include titanium nitride (TiN), tantalum nitride (TaN), and/or another suitable liner material.

The interconnect layer 104 of the semiconductor device 100 is included above the device layer 102 and above the integrated circuit devices 110 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include ILD layers 126 and ESLs 128 that are arranged in an alternating manner in the z-direction. The ILD layers 126 and the ESLs 128 may extend in the x-direction and/or in the y-direction in the semiconductor device 100.

The ILD layers 126 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 126 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 128 may each include a silicon nitride (SiₓN_{y}), silicon carbide (SiC), silicon oxynitride (SiON), and/or another suitable dielectric material. In some implementations, an ILD layer 126 and an ESL 128 include different dielectric materials to provide etch selectivity to enable various structures to be formed in the interconnect layer 104.

The metallization structures 130 and the interconnect structures 132 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, one or more liner layers are included between the metallization structures 130 and/or the interconnect structures 132 and the surrounding dielectric layers in the interconnect layer 104. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 130 and the interconnect structures 132 of the interconnect layer 104 may be arranged in a vertical manner (e.g., in the z-direction). In other words, a plurality of stacked metallization structures 130 and interconnect structures 132 may extend between the device layer 102 and a top of the interconnect layer 104 to facilitate electrical signals and/or power to be routed between the device layer 102 and connection structures (not shown) of the semiconductor device 100. The plurality of stacked metallization structures 130 may be arranged in layers that may be referred to as M-layers, and the plurality of stacked interconnect structures 132 may be arranged in layers that may be referred to as V-layers.

A bottom-most layer of interconnect structures in the interconnect layer 104 includes a plurality of conductive structures. The conductive structures are electrically coupled and/or physically coupled with one or more of the integrated circuit devices 110 in the device layer 102 and/or in the interconnect layer 104. The conductive structures enable signals and/or power to be provided to and/or from the integrated circuit devices 110.

The conductive structures include a combination of metallization structures 130 and interconnect structures 132. The metallization structures 130 may include trenches, conductive traces, and/or other types of conductive structures that primarily extend in the x-direction and/or in the y-direction in the interconnect layer 104. The interconnect structures 132 may include vias, plugs, conductive columns, and/or other types of conductive structures that primarily extend in the z-direction in the semiconductor device. In some implementations, a conductive structure in the interconnect layer 104 includes a dual damascene structure, which includes a combination of a metallization structure 130 and an interconnect structure 132.

The interconnect structures 132 in the interconnect layer 104 are electrically connected to the gate structures 116 and the source/drain contact structures 122 of the integrated circuit devices 110. The bottom-most layer of interconnect structures 132 includes source/drain interconnect structures 134 that are electrically coupled and/or physically coupled to the source/drain contact structures 122, and gate interconnect structures 136 that are electrically coupled and/or physically coupled to the gate structures 116. In some implementations, gate contacts (not shown) are included between the gate structures 116 and the gate interconnect structures 136. In some implementations, the bottom-most layer of interconnect structures 132 is referred to as a via-0 (V0) layer, the source/drain interconnect structures 134 are referred to source/drain vias (VDs), and the gate interconnect structures 136 are referred to as gate vias (VGs).

A metal-0 (M0) layer may be located above the source/drain interconnect structures 134 and the gate interconnect structures 136. The metallization structures 130 in the M0 layer may be coupled with the source/drain interconnect structures 134 and the gate interconnect structures 136. A via-1 (V1) layer that includes one or more interconnect structures 132 may be included above the M0 layer. A metal-1 layer (M1) layer may be located above the V1 layer in the interconnect layer 104, a via-2 (V2) layer may be included above the M1 layer, a metal-2 layer (M2) layer may be located above the V2 layer, and so on.

FIG. 1B illustrates a detailed view of a connection between a source/drain contact structure 122 and a source/drain interconnect structure 134 of the semiconductor device 100. As shown in FIG. 1B, the source/drain contact structure 122 may be included in the dielectric layer 108. An ESL 128 of the interconnect layer 104 may be included above the source/drain contact structure 122. An ILD layer 126 (e.g., an ILD1 layer) of the interconnect layer 104 may be included above the ESL 128.

As further shown in FIG. 1B, the source/drain interconnect structure 134 is located above and/or on the source/drain contact structure 122 such that the source/drain contact structure 122 and the source/drain interconnect structure 134 are vertically arranged (e.g., in the z-direction) in the semiconductor device 100. The top surface of the source/drain contact structure 122 is located below the ESL 128 and includes a recess 138 that is filled in by the bottom of the source/drain interconnect structure 134. Thus, the top surface of the source/drain contact structure 122 is recessed below the ESL 128, and the bottom of the source/drain interconnect structure 134 is recessed in the top surface of the source/drain contact structure 122.

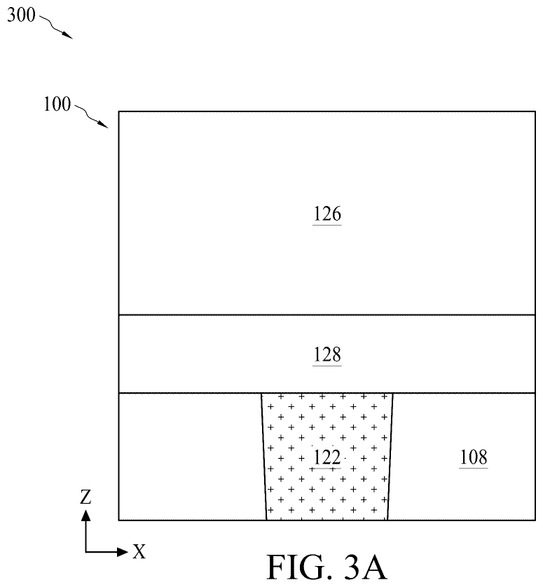

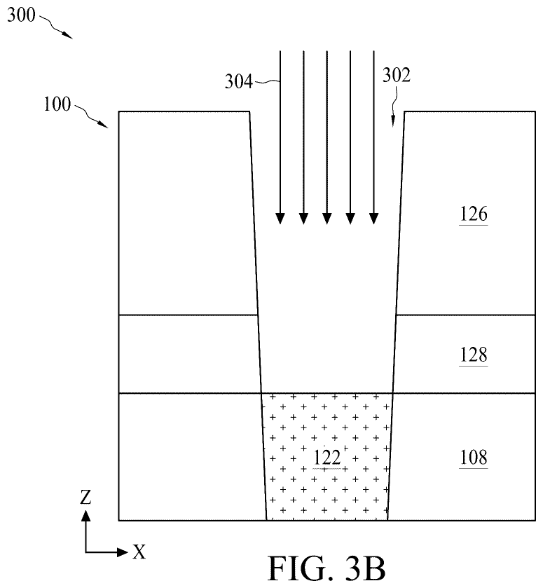

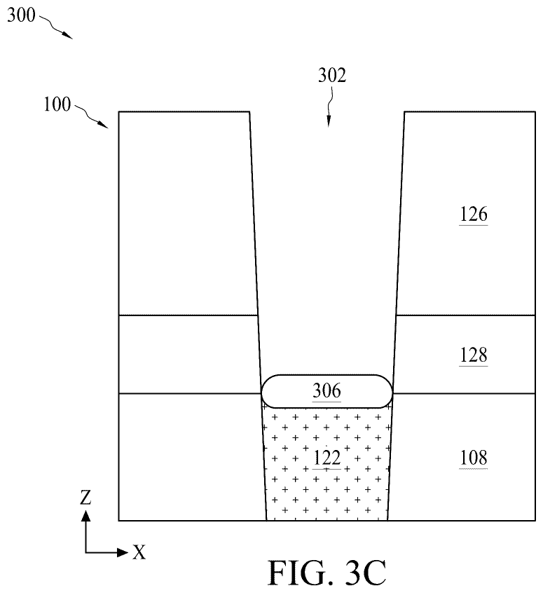

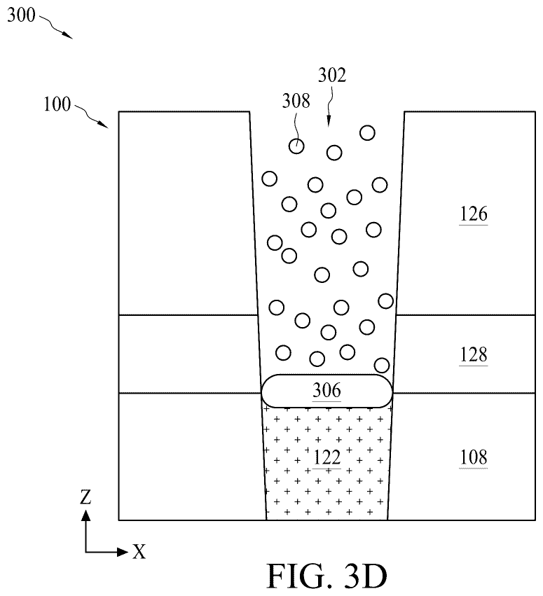

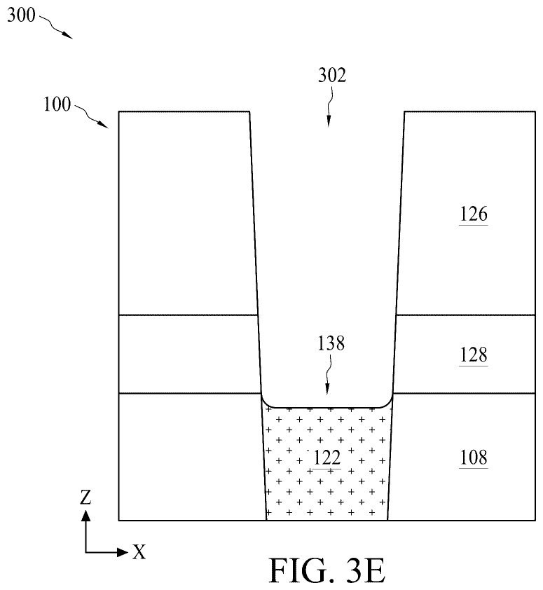

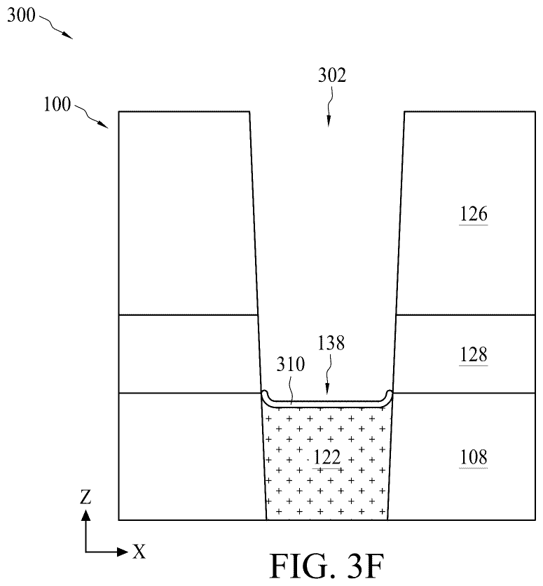

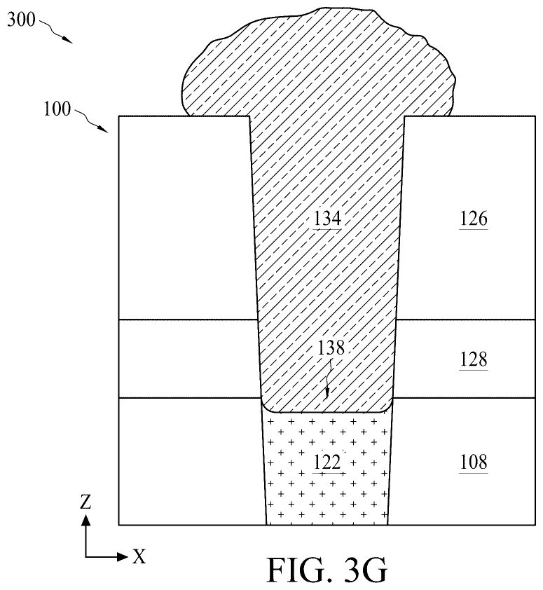

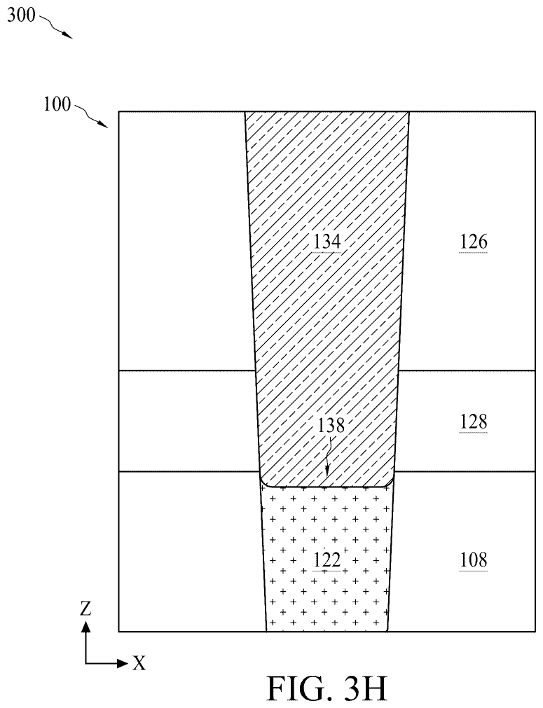

The recess 138 in the top surface of the source/drain contact structure 122 results from a pre-clean process that is performed on the top surface of the source/drain contact structure 122 to remove a metal-oxide layer (e.g., native oxides) from the top surface of the source/drain contact structure 122 prior to forming the source/drain interconnect structure 134 on the top surface of the source/drain contact structure 122. An example pre-clean process is described in connection with FIGS. 3A-3H.

The recess 138 provides increased surface area contact between the top surface of the source/drain contact structure 122 and the bottom of the source/drain interconnect structure 134. The source/drain contact structure 122 and the source/drain interconnect structure 134 may include different types of metals (e.g., the source/drain contact structure 122 may include tungsten (W) and the source/drain interconnect structure 134 may include copper (Cu)), and the hetero-metal interface between the source/drain contact structure 122 and the source/drain interconnect structure 134 may result in increased contact resistance between the source/drain contact structure 122 and the source/drain interconnect structure 134. Thus, the recess 138 may negate some of the increased contact resistance, and/or may enable a lower overall contact resistance to be achieved.

As further shown in FIG. 1B, the bottom of the source/drain interconnect structure 134 is located below the bottom of the ESL 128 because of the recess 138. A bottom surface of the source/drain interconnect structure 134 may have a rounded cross-sectional profile that conforms to the cross-sectional profile of the top surface of the source/drain contact structure 122.

As further shown in FIG. 1B, the source/drain contact structure 122 and/or the source/drain interconnect structure 134 may have one or more example dimensions. An example dimension D1 corresponds to a top lateral width of the source/drain interconnect structure 134 (e.g., a top width), and another example dimension D2 corresponds to a bottom lateral width of the source/drain interconnect structure 134 (e.g., a bottom width). The dimension D1 and the dimension D2 may each be included in a range of approximately 3 nanometers to approximately 50 nanometers. However, other values and ranges are within the scope of the present disclosure. In some implementations, the dimension D1 is greater than the dimension D2 such that the sidewalls of the source/drain interconnect structure 134 are angled outward from a center of the source/drain interconnect structure 134, and such that the lateral width of the source/drain interconnect structure 134 decreases from the dimension D1 to the dimension D2.

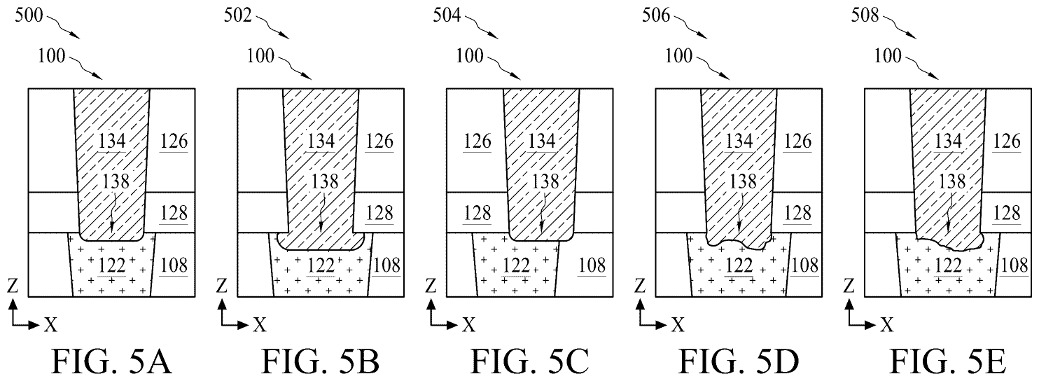

In some implementations, the dimension D2 also corresponds to a top lateral width of the top surface of the source/drain contact structure 122. In some implementations, the top lateral width of the top surface of the source/drain contact structure 122 is greater than the dimension D2 such that the top surface of the source/drain contact structure 122 extends laterally outward from the bottom of the source/drain interconnect structure 134, as shown in various examples in FIGS. 5A-5E.

Another example dimension D3 corresponds to a z-direction height (or vertical thickness) of the source/drain interconnect structure 134. In some implementations, the dimension D3 is included in a range of approximately 15 nanometers to approximately 45 nanometers. However, other values and ranges are within the scope of the present disclosure.

Another example dimension D4 corresponds to a z-direction height (or vertical thickness) of the source/drain contact structure 122. In some implementations, the dimension D4 is included in a range of approximately 15 nanometers to approximately 45 nanometers. However, other values and ranges are within the scope of the present disclosure.

In some implementations, a ratio of the dimension D3 to the dimension D4 is included in a range of approximately 1:4 to approximately 45:1. However, other values and ranges are within the scope of the present disclosure.

Another example dimension D5 includes a z-direction depth of the recess 138. The z-direction depth of the recess 138 corresponds to the vertical (e.g., z-direction) distance between the lowest part of the recess 138 and the bottom of the ESL 128. In some implementations, the dimension D5 is included in a range of approximately 0.5 nanometers to approximately 5 nanometers. If dimension D5 is outside of this range, the metal-oxide layer that forms on the top surface of the source/drain contact structure 122 may not be fully removed, resulting in increased contact resistance between the source/drain contact structure 122 and the source/drain interconnect structure 134. However, other values and ranges are within the scope of the present disclosure.

Another example dimension D6 includes a vertical (e.g., z-direction) distance between the lowest part of the recess 138 and the top of the ESL 128. In some implementations, the dimension D6 is included in a range of approximately 3 nanometers to approximately 12 nanometers. However, other values and ranges are within the scope of the present disclosure.

As indicated above, FIGS. 1A and 1B are provided as an example. Other examples may differ from what is described with regard to FIGS. 1A and 1B.

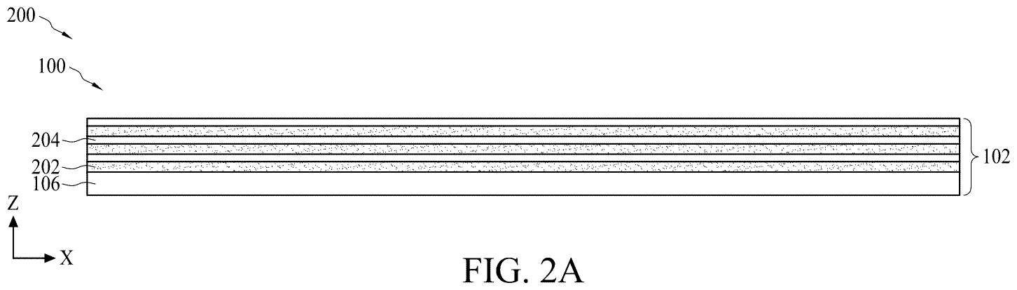

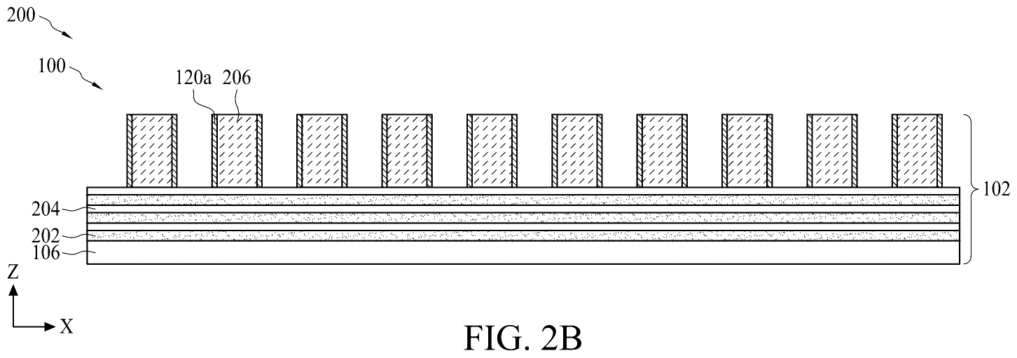

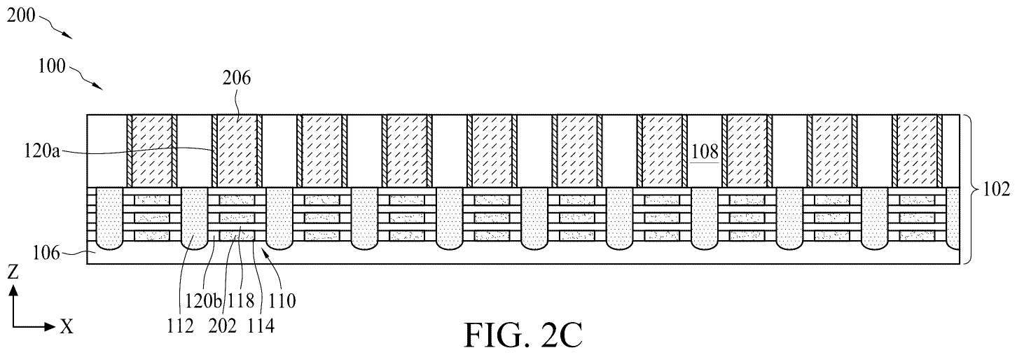

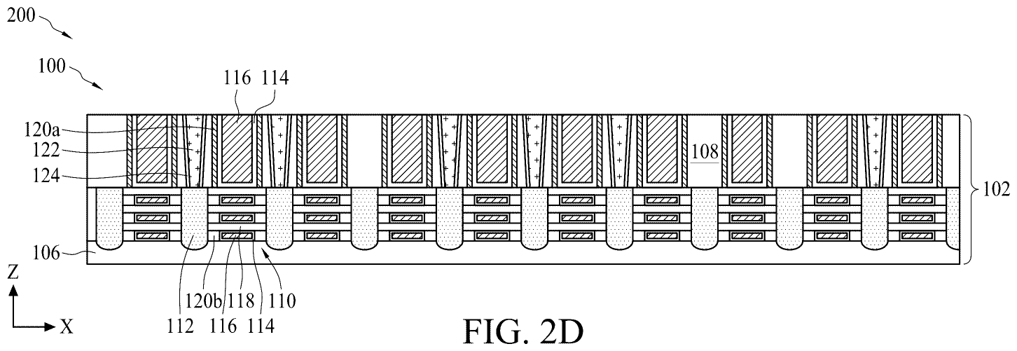

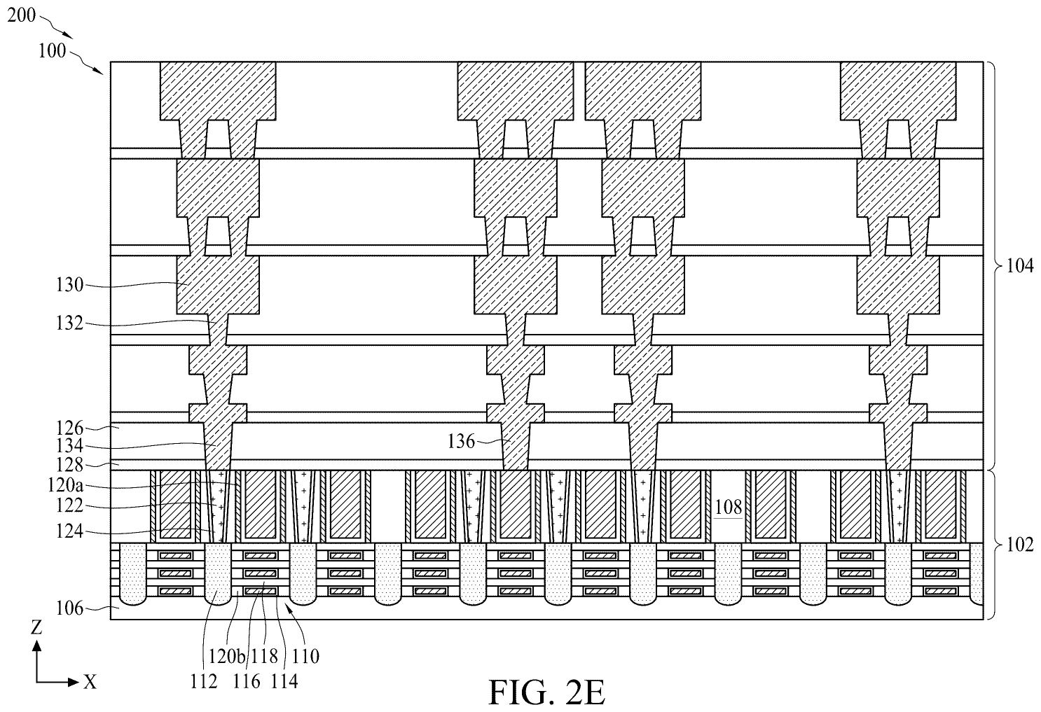

FIGS. 2A-2E are diagrams of an example implementation 200 of forming the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate layer 106 is provided. The substrate layer 106 may be provided in the form of a semiconductor wafer such as a silicon (Si) wafer, a silicon-on-insulator (SOI) wafer, and/or another type of semiconductor work piece. The semiconductor device 100 may be formed on the semiconductor wafer with other semiconductor devices.

A layer stack may be formed on the substrate layer 106. The layer stack may be referred to as a superlattice. The layer stack may include a plurality of alternating layers that are arranged in a direction (e.g., the z-direction) that is approximately perpendicular to the substrate layer 106. For example, the layer stack may include vertically alternating layers of sacrificial layers 202 and nanostructure channel layers 204 above the substrate layer 106. The quantity of the sacrificial layers 202 and the quantity of the nanostructure channel layers 204 illustrated in FIG. 2A are examples, and other quantities of the sacrificial layers 202 and the nanostructure channel layers 204 are within the scope of the present disclosure.

The sacrificial layers 202 enable a vertical distance to be defined between adjacent nanostructure channels that are formed from the nanostructure channel layers 204, and serve as placeholder layers for subsequently-formed gate structures of the integrated circuit devices 110 of the semiconductor device 100 that are formed around the nanostructure channels.

The sacrificial layers 202 include a first material composition, and the nanostructure channel layers 204 include a second material composition. In some implementations, the first material composition and the second material composition are the same material composition. In some implementations, the first material composition and the second material composition are different material compositions. As an example, the sacrificial layers 202 may include silicon germanium (SiGe) and the nanostructure channel layers 204 may include silicon (Si). This enables the sacrificial layers 202 and/or the nanostructure channel layers 204 to be selectively etched (e.g., enables the sacrificial layers 202 and not the nanostructure channel layers 204 to be etched, enables the nanostructure channel layers 204 and not the sacrificial layers 202 to be etched) depending on the type of etchant that is used.

One or more types of deposition tools may be used to deposit and/or grow the alternating layers of the layer stack to include nanostructures (e.g., nanosheets) on the substrate layer 106. For example, a deposition tool may be used to grow the sacrificial layers 202 and/or the nanostructure channel layers 204 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial layers 202 and/or the nanostructure channel layers 204 may be deposited by chemical vapor deposition (CVD), physical vapor deposition (PVD), atomic layer deposition (ALD), and/or another suitable deposition technique.

In the y-direction, which is not visible in the view in FIG. 2A, the layer stack and the substrate layer 106 may be etched to form fin structures that extend in the x-direction. A fin structure may include a portion of the layer stack and a portion of the substrate layer 106 under the layer stack. The fin structures may be formed by patterning the one or more masking layers and etching based on a pattern formed in one or more of the masking layers. The one or more masking layers may be patterned using photolithography techniques, including double-patterning or multi-patterning techniques. An etch tool may be used to etch the layer stack and the substrate layer 106 based on the pattern using a dry etch technique (e.g., reactive ion etching), a wet etch technique, and/or a combination thereof. In some implementations, shallow trench isolation (STI) regions (not shown) may be formed between adjacent fin structures in the y-direction.

As shown in FIG. 2B, dummy gate structures 206 (also referred to as dummy gate stacks or temporary gate structures) may be formed over portions of the layer stack of sacrificial layers 202 and nanostructure channel layers 204. The dummy gate structures 206 may extend in the y-direction and may be arranged in the x-direction such that the dummy gate structures 206 are approximately perpendicular to the fin structures. The dummy gate structures 206 are sacrificial structures that are to be replaced by replacement gate structures or replacement gate stacks at a subsequent processing stage for the integrated circuit devices 110 of the semiconductor device 100. The dummy gate structures 206 may also be used to define source/drain (S/D) recesses in which source/drain regions of the nanostructure transistors are formed in the layer stack of sacrificial layers 202 and nanostructure channel layers 204.

The dummy gate structures 206 may include polycrystalline silicon (polysilicon or PO) or another material. The layers of the dummy gate structures 206 may be formed using various semiconductor processing techniques such depositing the layers of the dummy gate structures 206, patterning the layers of the dummy gate structures 206 to define the dummy gate structures 206, and/or other semiconductor processing techniques. The sidewall spacers 120a may be formed on the sidewalls of the dummy gate structures 206.

As shown in FIG. 2C, the source/drain regions 112 of the integrated circuit devices 110 are formed in the layer stack of sacrificial layers 202 and nanostructure channel layers 204. To form the source/drain regions 112, source/drain recesses may be formed through the layer stack of sacrificial layers 202 and nanostructure channel layers 204 in an etch operation. The source/drain recesses may be formed on opposing sides of a dummy gate structure 206 in the x-direction. The etch operation may be performed using the etch tool and may be referred to a strained source/drain (SSD) etch operation. In some implementations, the etch operation includes the use of a plasma etch technique, a wet chemical etch technique, and/or another type of etch technique.

Formation of the source/drain recesses may define the channel layers 118. The channel layers 118 may include silicon-based nanostructures (e.g., nanosheets or nanowires, among other examples) that function as the semiconductive channels of the integrated circuit devices 110 of the semiconductor device 100. The channel layers 118 are arranged in a direction (e.g., the z-direction) that is approximately perpendicular to the substrate layer 106. In other words, the channel layers 118 are vertically arranged or stacked above the substrate layer 106.

Prior to formation of the source/drain regions 112 in the source/drain recesses, the ends of the sacrificial layers 202 that are exposed in the source/drain recesses may be laterally etched in an etch operation, thereby forming cavities in the ends of the sacrificial layers 202. The inner spacers 120b may be formed in the cavities. To form the inner spacers 120b, a deposition tool may be used to deposit a layer of dielectric material in the cavities and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 120b in the cavities.

After formation of the inner spacers 120b, the source/drain recesses may be filled with one or more layers of epitaxial material to form the source/drain regions 112 in the source/drain recesses. For example, a deposition tool may be used to deposit a buffer region at the bottom of the source/drain recess, and a deposition tool may deposit a source/drain region 112 on the buffer region in the source/drain recess. In some implementations, a deposition tool is used to deposit a capping layer on the source/drain region 112 in the source/drain recess. As another example, a deposition tool may epitaxially grow a first layer of a source/drain region 112 (referred to as an L1) over an associated buffer region (which may be referred to as an L0), and may epitaxially grow a second layer of the source/drain region 112 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 100 and to reduce dopant extrusion or migration into the channel layers 118. The second layer may include a highly doped silicon or highly doped silicon germanium. The second layer may be included to provide a compressive stress in the source/drain regions 112 to reduce boron loss.

As further shown in FIG. 2C, the dielectric layer 108 may be formed over the source/drain regions 112 and around the dummy gate structures 206. The dielectric layer 108 may fill in areas between the dummy gate structures 206. In some implementations, a contact etch stop layer (CESL) is conformally deposited (e.g., by a deposition tool) over the source/drain regions 112 prior to formation of the dielectric layer 206. The dielectric layer 108 is then formed on the CESL. The CESL may provide a mechanism to stop an etch process when forming source/drain contacts 122 for the source/drain regions 112. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 2D, a replacement gate process may be performed to replace the dummy gate structures 206 with the gate structures 116 of the integrated circuit devices 110. A dummy gate removal operation may be performed to remove the dummy gate structures 206 from the semiconductor device 100. The removal of the dummy gate structures 206 leaves behind openings (or recesses) in the dielectric layer 108, and provides access to the underlying sacrificial layers 202. The dummy gate structures 206 may be removed in one or more etch operations. Such etch operations may include a plasma etch technique, a wet chemical etch technique, and/or another type of etch technique.

The replacement gate process may include a nanostructure release operation (e.g., an SiGe release operation). The nanostructure release operation is performed to remove the sacrificial layers 202 (e.g., the silicon germanium layers). This results in openings between the channel layers 118 (e.g., the areas around the channel layers 118). The sacrificial layers 202 may be removed through the spaces that were previously occupied by the dummy gate structures 206. The nanostructure release operation may include the use of an etch tool to perform an etch operation to remove the sacrificial layers 202 based on a difference in etch selectivity between the material of the sacrificial layers 202 and the material of the channel layers 118, and between the material of the sacrificial layers 202 and the material of the inner spacers 120b. The inner spacers 120b may function as etch stop layers in the etch operation to protect the source/drain regions 112 from being etched.

The replacement gate operation includes forming gate dielectric layers 114 and gate structures (e.g., replacement gate structures) 116 of the integrated circuit devices 110 in the openings between the source/drain regions 112 and between the inner spacers 120b. In particular, the gate dielectric layers 114 and the gate structures 116 fill the areas between and around the channel layers 118 that were previously occupied by the sacrificial layers 202 such that the gate structures 116 fully wrap around the channel layers 118 and surround the channel layers 118. This increases control of the channel layers 118, increases drive current for the integrated circuit devices 110, and/or reduces short channel effects (SCEs) for the integrated circuit devices 110, among other examples. The gate structures 116 may also fill in the spaces that were previously occupied by the dummy gate structures 206. Portions of a gate structure 116 are formed in between pairs of channel layers 118 in an alternating vertical arrangement. In other words, the semiconductor device 100 includes one or more vertical stacks of alternating channel layers 118 and portions of a gate structure 116.

As further shown in FIG. 2D, the source/drain contact structures 122 of the integrated circuit devices 110 may be formed through the dielectric layer 108. The source/drain contact structures 122 may be formed in recesses in the dielectric layer 108. In some implementations, a pattern in a photoresist layer is used to etch the dielectric layer 108 to form the recesses. In these implementations, a deposition tool may be used to form the photoresist layer on the dielectric layer 108. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 108 based on a pattern to form the recesses.

The source/drain contact structures 122 may be formed in the recesses such that the source/drain contact structures 122 land on the source/drain regions 112. A deposition tool may be used to deposit the material of the source/drain contact structures 122 in the recesses using a CVD technique, a PVD technique, an ALD technique, an electroplating technique, and/or another suitable deposition technique. The material of the source/drain contact structures 122 may be deposited in one or more deposition operations. In some implementations, a seed layer is first deposited, and the material of the source/drain contact structures 122 is deposited on the seed layer. In some implementations, one or more liner layers 124 are deposited in the recesses, and the source/drain contact structures 122 are deposited on the liner layer(s) 124. In some implementations, a planarization tool is used to perform a planarization operation (e.g., a CMP operation) to planarize the source/drain contact structures 122 after the source/drain contact structures 122 are deposited such that the tops of the source/drain contact structures 122 are approximately co-planar with the top of the dielectric layer 108.

As shown in FIG. 2E, the interconnect layer 104 of the semiconductor device 100 is formed above the dielectric layer 108. One or more deposition tools are used to deposit alternating layers of ILD layers 126 and ESLs 128 in the interconnect layer 104 of the semiconductor device 100. In this way, the ILD layers 126 and ESLs 128 may be arranged in the z-direction in the semiconductor device 100. One or more deposition tools may be used to deposit each of the ILD layers 126 and each of the ESLs 128 using a PVD technique, an ALD technique, a CVD technique, an oxidation technique, and/or another suitable deposition technique. In some implementations, a planarization tool may be used to planarize the ILD layers 126 and/or the ESLs 128 after the ILD layers 126 and/or the ESLs 128 are deposited.

As further shown in FIGS. 2E, a deposition tool, an exposure tool, a developer tool, an etch tool, a planarization tool, a plating tool, and/or another semiconductor processing tool may be used to perform various operations to form the source/drain interconnect structures 134 and/or the gate interconnect structures 136 at the bottom of the interconnect layer 104. One or more source/drain interconnect structures 134 may be formed on one or more source/drain contact structures 122 of one or more integrated circuit devices 110. One or more gate interconnect structures 136 may be formed on one or more gate structures 116 of one or more integrated circuit devices 110.

A deposition tool, an exposure tool, a developer tool, an etch tool, a planarization tool, a plating tool, and/or another semiconductor processing tool may be used to perform various operations to form the metallization structures 130 and to form the interconnect structures 132 in the interconnect layer 104 of the semiconductor device 100. In some implementations, the interconnect layer 104 may be formed in a plurality of layers. For example, an ILD layer 126 and an ESL 128 may be formed (e.g., using one or more deposition tools and/or one or more planarization tools), recesses may be formed in and/or through the ILD layer 126 and the ESL 128 (e.g., using an exposure tool, a developer tool, and/or an etch tool), and a layer of metallization structures 130 (e.g., the M0 layer) may be formed in the ILD layer 126 and the ESL 128 (e.g., using one or more deposition tools and/or one or more planarization tools). Another ILD layer 126 and another ESL 128 may be formed, and a layer of interconnect structures 132 (e.g., the V1 layer) may be formed in the ILD layer 126 and the ESL 128. Additional layers of metallization structures 130 and additional layers of interconnect structures 132 may be formed in a similar manner.

One or more deposition tools may be used to deposit the source/drain interconnect structures 134, the gate interconnect structures 136, the metallization structures 130, and/or the interconnect structures 132 using a PVD technique, an ALD technique, a CVD technique, an electroplating technique (e.g., an electro-chemical plating technique), and/or another suitable deposition technique. In some implementations, a planarization tool may be used to planarize the source/drain interconnect structures 134, the gate interconnect structures 136, the metallization structures 130, and/or the interconnect structures 132 after the source/drain interconnect structures 134, the gate interconnect structures 136, the metallization structures 130, and/or the interconnect structures 132 are deposited.

As indicated above, FIGS. 2A-2E are provided as an example. Other examples may differ from what is described with regard to FIGS. 2A-2E.

FIGS. 3A-3H are diagrams of an example implementation 300 of forming a source/drain interconnect structure 134 described herein. In some implementations, one or more of the semiconductor processing operations described in connection with FIGS. 3A-3H may be performed using one or more semiconductor processing tools, such as a deposition tool, an exposure tool, a developer tool, an etch tool, a planarization tool, an ion implantation tool, a wafer/die transport tool, and/or another type of semiconductor processing tool. In some implementations, one or more of the semiconductor processing operations described in connection with FIGS. 3A-3H may be performed as part of the process for forming the semiconductor device 100 illustrated and described in connection with FIGS. 2A-2E.

As shown in FIG. 3A, a source/drain contact structure 122 of the semiconductor device 100 may be formed in the dielectric layer 108. The ESL 128 may be formed over and/or on the dielectric layer 108, and over and/or on the source/drain contact structure 122 such that the ESL 128 covers the top surface of the source/drain contact structure 122.

As shown in FIG. 3B, a recess 302 is formed through the ILD layer 126 and through the ESL 128. The recess 302 is formed to the source/drain contact structure 122 so that the top surface of the source/drain contact structure 122 is exposed in the recess 302.

In some implementations, a pattern in a photoresist layer is used to etch the ILD layer 126 and/or the ESL 128 to form the recess 302. In these implementations, a deposition tool may be used to form the photoresist layer on the ILD layer 126 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 126 and/or the ESL 128 based on the pattern using an etchant 304 to form the recess 302. In some implementations, the etch operation includes a dry etch operation (e.g., an etch operation using a plasma-based etchant 304, an etch operation using a gas-based etchant 304), a wet chemical etch operation (e.g., an etch operation using a wet chemical etchant 304), and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 302 based on a pattern.

As shown in FIG. 3C, a metal-oxide layer 306 may form on the top surface of the source/drain contact structure 122 in the recess 302. The metal-oxide layer 306 may be referred to a “native oxide” in that the metal-oxide layer 306 naturally forms due to oxidation of the top surface of the source/drain contact structure 122. The top surface of the source/drain contact structure 122 may oxidize due to exposure to various oxygen sources, such as oxygen in the atmosphere in the processing chamber of the etch tool, oxygen in the atmosphere in a semiconductor manufacturing facility in which the semiconductor device 100 is manufactured, and/or from another oxygen source. In some implementations, the top surface of the source/drain contact structure 122 may oxidize due to exposure to oxygen while being queued for the next processing step for the semiconductor device 100.

The metal-oxide layer 306 may correspond to a portion of the top surface of the source/drain contact structure 122 to which atmospheric oxygen has bonded. Thus, the metal-oxide layer 306 contains a metal of the source/drain contact structure 122 and extends below the ESL 128. For example, if the source/drain contact structure 122 includes tungsten (W), the metal-oxide layer 306 may include oxidized tungsten (or a tungsten oxide (WOₓ such as WO₃)). As another example, if the source/drain contact structure 122 includes molybdenum (Mo), the metal-oxide layer 306 may include oxidized molybdenum (or a molybdenum oxide (MoOₓ such as MoO₃)).

As shown in FIGS. 3D and 3E, a pre-cleaning operation may be performed to remove the metal-oxide layer 306 from the top surface of the source/drain contact structure 122. The metal-oxide layer 306 may be removed from the top surface of the source/drain contact structure 122 to provide a bare-metal substrate on which a source/drain interconnect structure 134 is to be formed on the source/drain contact structure 122 in the recess 302.

In some implementations, the pre-cleaning operation is performed in a processing chamber of a deposition tool such as a CVD tool or a PVD tool. This enables the pre-cleaning operation to be performed in the processing chamber that is to be used for deposition of the material of the source/drain interconnect structure 134. In other words, the pre-cleaning operation and deposition of the material of the source/drain interconnect structure 134 may be performed in the same processing chamber of the deposition tool. This enables the pre-cleaning operation and the deposition of the material of the source/drain interconnect structure 134 to be performed under the same vacuum (e.g., while maintaining the vacuum in the processing chamber), which reduces the likelihood that the metal-oxide layer 306 will regrow on the top surface of the source/drain contact structure 122 in the recess 302 before the source/drain interconnect structure 134 is formed.

As shown in FIG. 3D, the pre-cleaning operation includes the use of a pre-cleaning agent 308. The pre-cleaning agent 308 may include a wet chemical pre-cleaning agent, a dry gas pre-cleaning agent, and/or another type of pre-cleaning agent. The pre-cleaning agent 308 is provided into the recess 302 (e.g., using the deposition tool or a dedicated pre-cleaning tool) so that the metal-oxide layer 306 is soaked in the pre-cleaning agent 308 for a time duration.

The pre-cleaning agent 308 includes a metal precursor that etches or removes material from the metal-oxide layer 306. For example, the pre-cleaning agent 308 may include a halogen-based metal precursor, such as a transition metal halide. Examples of transition metal halides for the pre-cleaning agent 308 may include a tungsten fluoride (e.g., WF₆), a tungsten chloride (e.g., WCl₆, WCl₅), a molybdenum chloride (e.g., MoCl₆, MoCl₅), a tantalum chloride (e.g., TaCl₅), and/or a titanium chloride (e.g., TiCl₄), among other examples. In some implementations, the pre-cleaning agent 308 includes a metal precursor of the material of the source/drain contact structure 122. In some implementations, the pre-cleaning agent 308 includes a metal precursor of the material of the source/drain interconnect structure 134. In these implementations, the pre-cleaning operation may be performed as part of depositing the source/drain interconnect structure 134, which reduces the process complexity of manufacturing the semiconductor device 100.

The metal precursor of the pre-cleaning agent 308 selectively etches the metal-oxide layer 306 with minimal to no etching of the ILD layer 126 and/or the ESL 128. In this way, the pre-cleaning agent 308 removes the metal-oxide layer 306 with minimal to no widening of the recess 302. Therefore, the use of the metal precursor for the pre-cleaning agent 308 enables the aspect ratio (e.g., the ratio of the height to the width) of the recess 302 to be maintained.

In some implementations, the metal precursor of the pre-cleaning agent 308 is a tungsten precursor. For example, the tungsten precursor may be a tungsten fluoride (WFₓ) (e.g., a tungsten fluoride gas) such as tungsten hexafluoride (WF₆). In these implementations, the pre-cleaning operation may performed at a temperature in the processing chamber that is included in a range of approximately 200 degrees Celsius to approximately 450 degrees Celsius to promote a reaction between the tungsten fluoride of the pre-cleaning agent 308 and the metal-oxide layer 306. However, other values and ranges are within the scope of the present disclosure. Additionally and/or alternatively, the pre-cleaning operation may performed at a pressure in the processing chamber that is included in a range of approximately 0.1 Torr to approximately 50 Torr to promote a reaction between the tungsten fluoride of the pre-cleaning agent 308 and the metal-oxide layer 306. However, other values and ranges are within the scope of the present disclosure.

As another example, the tungsten precursor may be a tungsten chloride (WClₓ) (e.g., a tungsten chloride gas, a tungsten chloride liquid) such as tungsten hexachloride (WCl₆). In these implementations, the pre-cleaning operation may performed at a temperature in the processing chamber that is included in a range of approximately 200 degrees Celsius to approximately 450 degrees Celsius to promote a reaction between the tungsten chloride of the pre-cleaning agent 308 and the metal-oxide layer 306. However, other values and ranges are within the scope of the present disclosure. Additionally and/or alternatively, the pre-cleaning operation may performed at a pressure in the processing chamber that is included in a range of approximately 0.1 Torr to approximately 50 Torr to promote a reaction between the tungsten chloride of the pre-cleaning agent 308 and the metal-oxide layer 306. However, other values and ranges are within the scope of the present disclosure.

In some implementations, the metal precursor of the pre-cleaning agent 308 is a molybdenum precursor. For example, the molybdenum precursor may be a molybdenum fluoride (MoFₓ) (e.g., a molybdenum fluoride gas) such as molybdenum hexafluoride (MoF₆). In these implementations, the pre-cleaning operation may performed at a temperature in the processing chamber that is included in a range of approximately 200 degrees Celsius to approximately 450 degrees Celsius to promote a reaction between the molybdenum fluoride of the pre-cleaning agent 308 and the metal-oxide layer 306. However, other values and ranges are within the scope of the present disclosure. Additionally and/or alternatively, the pre-cleaning operation may performed at a pressure in the processing chamber that is included in a range of approximately 0.1 Torr to approximately 260 Torr to promote a reaction between the molybdenum fluoride of the pre-cleaning agent 308 and the metal-oxide layer 306. However, other values and ranges are within the scope of the present disclosure.

As another example, the molybdenum precursor may be a molybdenum chloride (MoClₓ) (e.g., a molybdenum chloride gas, a molybdenum chloride liquid) such as molybdenum pentachloride (MoCl₅). In these implementations, the pre-cleaning operation may performed at a temperature in the processing chamber that is included in a range of approximately 200 degrees Celsius to approximately 450 degrees Celsius to promote a reaction between the molybdenum chloride of the pre-cleaning agent 308 and the metal-oxide layer 306. However, other values and ranges are within the scope of the present disclosure. Additionally and/or alternatively, the pre-cleaning operation may performed at a pressure in the processing chamber that is included in a range of approximately 0.1 Torr to approximately 260 Torr to promote a reaction between the molybdenum chloride of the pre-cleaning agent 308 and the metal-oxide layer 306. However, other values and ranges are within the scope of the present disclosure.

As shown in FIG. 3E, the pre-cleaning operation results in the top surface of the source/drain contact structure 122 becoming recessed. The pre-cleaning agent 308 removes metal and oxygen constituents from the metal-oxide layer 306, and the metal constituent corresponds to the metal of the source/drain contact structure 122. Therefore, removal of the metal-oxide layer 306 using the pre-cleaning agent 308 results in removal of metal from the top surface of the source/drain contact structure 122.

FIG. 3F illustrates an alternative implementation in which a residue layer 310 is left behind on the top surface of the source/drain contact structure 122 after the pre-cleaning operation. The residue layer 310 may be a metal element from the pre-cleaning agent 308. For example, if a molybdenum chloride (MoClₓ) is used as the pre-cleaning agent, the residue layer 310 may include a layer of molybdenum on the surface of the source/drain contact structure 122. Thus, if the source/drain contact structure 122 is formed of tungsten (W), the top surface of the source/drain contact structure 122 may have a thin layer of molybdenum.

As shown in FIG. 3G, the material of a source/drain interconnect structure 134 is formed on the top surface of the source/drain contact structure 122 in the recess 302. The material of the source/drain interconnect structure 134 fills in the recess 302. A deposition tool (e.g., the same deposition tool, using the same processing chamber, that was used to perform the pre-clean operation) may be used to deposit the material of the source/drain interconnect structure 134 using a CVD technique, and ALD technique, a PVD technique, an electroplating technique, and/or another suitable deposition technique.

A metal precursor may be used to deposit the material of the source/drain interconnect structure 134. The metal precursor may be the same metal precursor that was used as the pre-cleaning agent 308 for the pre-cleaning operation, or may be a different metal precursor. The metal precursor used to deposit the material of the source/drain interconnect structure 134 may selectively deposit on metals such as the top surface of the source/drain contact structure 122. This enables the material of the source/drain interconnect structure 134 to be deposited in a “bottom-up” type of material growth, where the material of the source/drain interconnect structure 134 builds up on the top surface of the source/drain contact structure 122 and not on the sidewalls of the recess 302 corresponding to the ILD layer 126 and the ESL 128. The bottom-up type of material growth for the source/drain interconnect structure 134 reduces the likelihood of formation of voids in the source/drain interconnect structure 134.

In some implementations, the source/drain interconnect structure 134 is formed of tungsten (W), and a tungsten precursor used to deposit the material of the source/drain interconnect structure 134. For example, the tungsten precursor may be a tungsten fluoride (WFₓ) (e.g., a tungsten fluoride gas) such as tungsten hexafluoride (WF₆). As another example, the tungsten precursor may be a tungsten chloride (WClₓ) (e.g., a tungsten chloride gas, a tungsten chloride liquid) such as tungsten hexachloride (WCl₆). The deposition of the material of the source/drain interconnect structure 134 using the tungsten precursor may be performed a temperature in the processing chamber of the deposition tool that is included in a range of approximately 200 degrees Celsius to approximately 450 degrees Celsius. However, other values and ranges are within the scope of the present disclosure. Additionally and/or alternatively, the deposition of the material of the source/drain interconnect structure 134 using the tungsten precursor may be performed at a pressure in the processing chamber that is included in a range of approximately 0.1 Torr to approximately 50 Torr. However, other values and ranges are within the scope of the present disclosure. In some implementations, the tungsten precursor may be used with or without a treatment gas such as a hydrogen (H₂) gas and/or an ammonia (NH₃) gas, among other examples.

In some implementations, the source/drain interconnect structure 134 is formed of molybdenum (Mo), and a molybdenum precursor used to deposit the material of the source/drain interconnect structure 134. For example, the molybdenum precursor may be a molybdenum fluoride (MoFₓ) (e.g., a molybdenum fluoride gas) such as molybdenum hexafluoride (MoF₆). The deposition of the material of the source/drain interconnect structure 134 using the molybdenum fluoride as a precursor may be performed a temperature in the processing chamber of the deposition tool that is included in a range of approximately 200 degrees Celsius to approximately 450 degrees Celsius. However, other values and ranges are within the scope of the present disclosure. In some implementations, the deposition of the material of the source/drain interconnect structure 134 using the molybdenum fluoride as a precursor may be performed at a pressure in the processing chamber that is included in a range of approximately 0.1 Torr to approximately 260 Torr. However, other values and ranges are within the scope of the present disclosure. In some implementations, the molybdenum fluoride may be used with or without a treatment gas such as a hydrogen (H₂) gas, among other examples.

As another example, the molybdenum precursor may be a molybdenum chloride (MoClₓ) (e.g., a molybdenum chloride gas, a molybdenum chloride liquid) such as molybdenum pentachloride (MoCl₅). The deposition of the material of the source/drain interconnect structure 134 using the molybdenum chloride as a precursor may be performed a temperature in the processing chamber of the deposition tool that is included in a range of approximately 300 degrees Celsius to approximately 450 degrees Celsius. However, other values and ranges are within the scope of the present disclosure. In some implementations, the deposition of the material of the source/drain interconnect structure 134 using the molybdenum chloride as a precursor may be performed at a pressure in the processing chamber that is included in a range of approximately 0.1 Torr to approximately 300 Torr. However, other values and ranges are within the scope of the present disclosure. In some implementations, the molybdenum chloride may be used with or without a treatment gas such as a hydrogen (H₂) gas, among other examples.

In some implementations, the source/drain interconnect structure 134 is formed of ruthenium (Ru), and a ruthenium precursor used to deposit the material of the source/drain interconnect structure 134. For example, the ruthenium precursor may be a ruthenium oxide (RuOₓ such as RuO₂). The deposition of the material of the source/drain interconnect structure 134 using the ruthenium oxide as a precursor may be performed a temperature in the processing chamber of the deposition tool that is included in a range of approximately 200 degrees Celsius to approximately 450 degrees Celsius. However, other values and ranges are within the scope of the present disclosure. In some implementations, the deposition of the material of the source/drain interconnect structure 134 using the ruthenium oxide as a precursor may be performed at a pressure in the processing chamber that is included in a range of approximately 0.1 Torr to approximately 260 Torr. However, other values and ranges are within the scope of the present disclosure. In some implementations, the ruthenium precursor may be used with or without a treatment gas such as a hydrogen (H₂) gas, among other examples.

In some implementations, the source/drain interconnect structure 134 is formed of cobalt (Co), and a cobalt precursor used to deposit the material of the source/drain interconnect structure 134. For example, the cobalt precursor may be a cobalt chloride (CoClₓ such as CoCl₂), a combination of a cobalt sulfate (CoSₓ) and a cobalt oxide (CoO_{y}), and/or another cobalt precursor. In some implementations, the cobalt precursor may be used with or without a treatment such as Dimethylamine borane (DMAB), ammonium chloride (NH₄Cl), and/or a boron hydroxide (BOₓH_{y}), among other examples. In some implementations, the pH of the treatment chemical may be included in a range of approximately 6 to approximately 9. However, other values and ranges are within the scope of the present disclosure.

In some implementations, the source/drain interconnect structure 134 is formed of copper (Cu), and a copper precursor used to deposit the material of the source/drain interconnect structure 134. For example, the copper precursor may be a copper chloride (CuClₓ such as CuCl₂), a combination of a copper sulfate (CuSₓ) and a copper oxide (CuO_{y}), and/or another copper precursor. In some implementations, the copper precursor may be used with or without a treatment such as a cobalt/carbon/hydrogen/nitrogen compound (CoCₓH_{y}N_{z}) and/or a carbon hydroxide (CHₓO_{y}), among other examples. In some implementations, the pH of the treatment chemical may be included in a range of approximately 7 to approximately 10. However, other values and ranges are within the scope of the present disclosure.

As shown in FIG. 3H, a planarization tool may be used to perform a planarization operation (e.g., a CMP operation) to planarize the source/drain interconnect structure 134. In this way, the top surface of the source/drain interconnect structure 134 may be substantially coplanar with the top surface of the ILD layer 126.

As indicated above, FIGS. 3A-3H are provided as an example. Other examples may differ from what is described with regard to FIGS. 3A-3H.

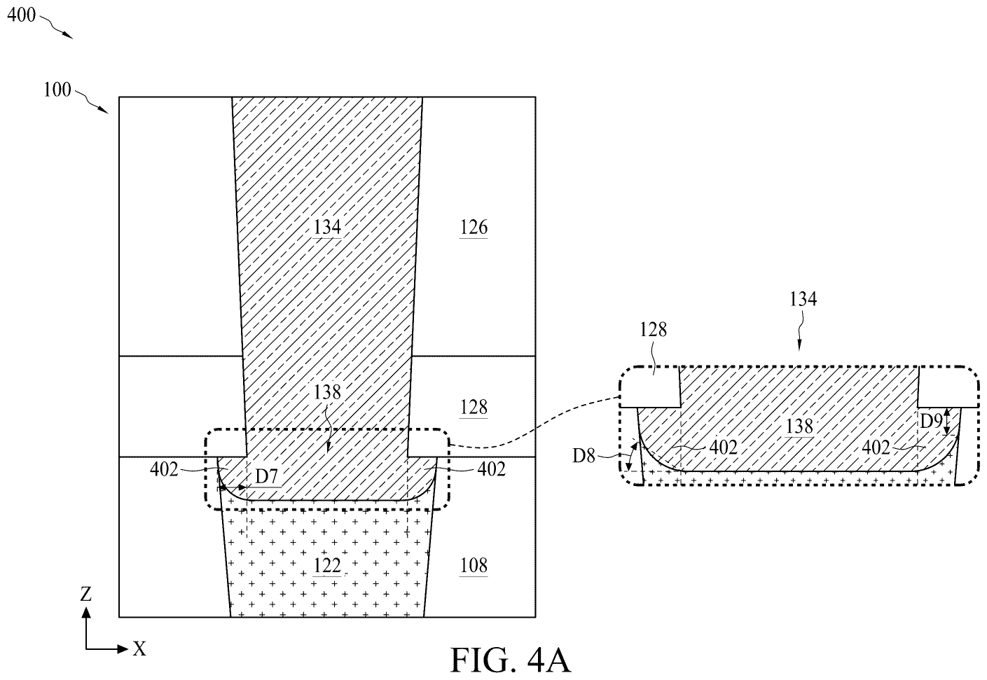

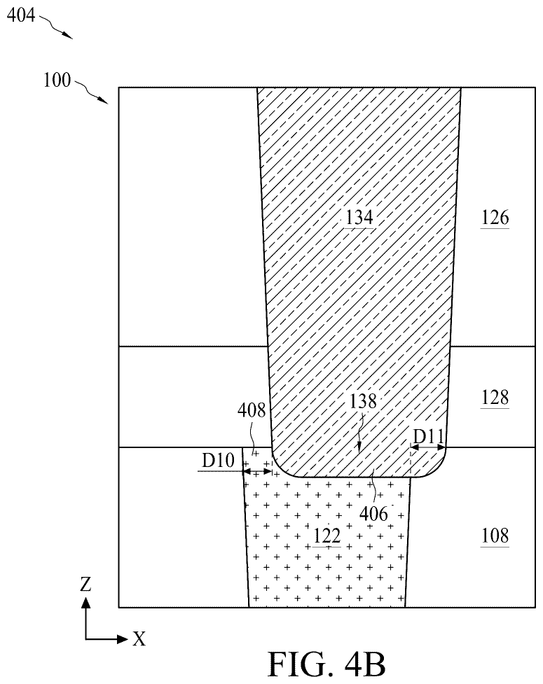

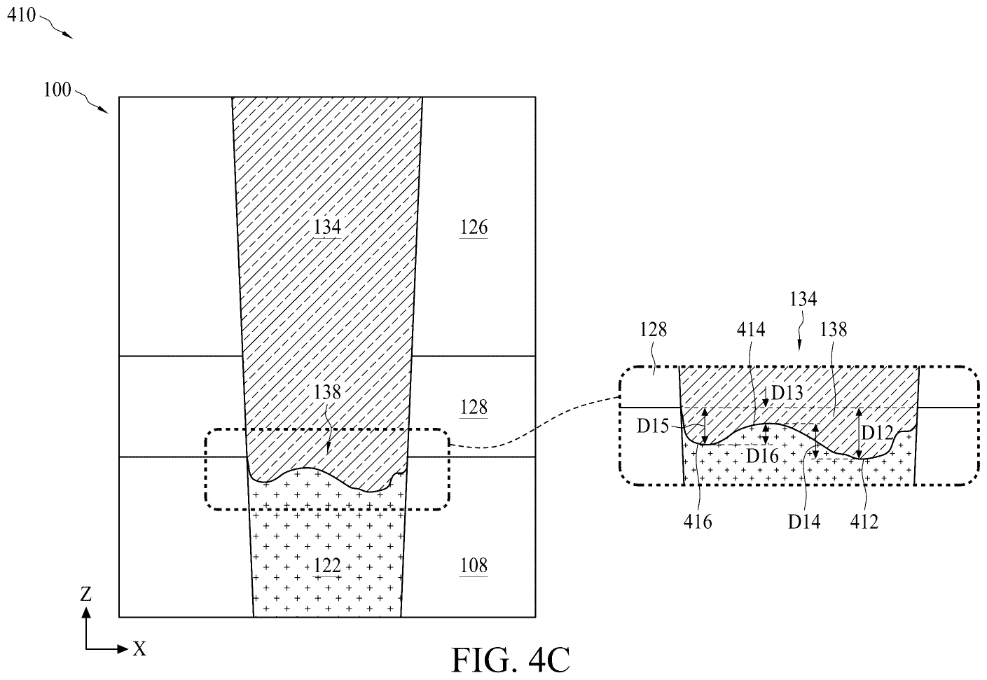

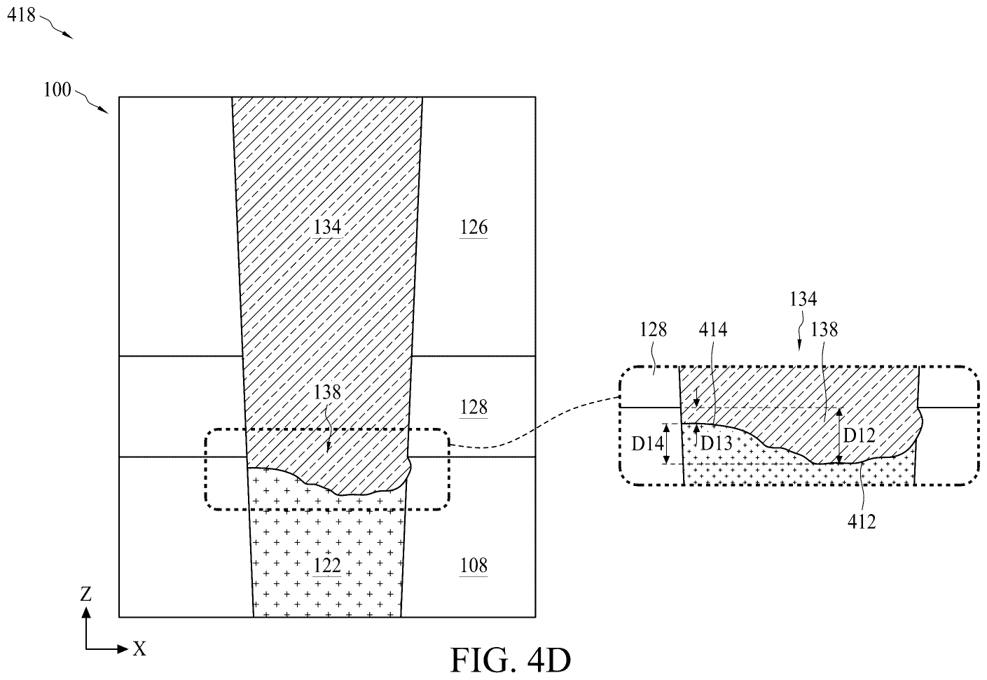

FIGS. 4A-4D are diagrams of example implementations of source/drain contact structures 122 and source/drain interconnect structures 134 for the semiconductor device 100 described herein. FIG. 4A illustrates an example implementation 400 of a source/drain contact structure 122 and a source/drain interconnect structure 134. As shown in FIG. 4A, the source/drain contact structure 122 and the source/drain interconnect structure 134 in the example implementation 400 are similar to the source/drain interconnect structure 134 in the example implementation illustrated in FIG. 1B.

However, in the example implementation 400, the bottom portion of the source/drain interconnect structure 134 in the recess 138 of the source/drain contact structure 122 includes extension regions 402 that extend laterally outward past the sidewalls of the source/drain interconnect structure 134. This may occur due to lateral etching in the top surface of the source/drain contact structure 122 during the pre-cleaning operation described in connection with FIGS. 3D and 3E. In some implementations, a lateral width (dimension D7) of an extension region 402 may be greater than 0 nanometers and up to approximately 5 nanometers. However, other values and ranges are within the scope of the present disclosure.

As further shown in a close-up view in FIG. 4A, the bottom portion of the source/drain interconnect structure 134 may have rounded corners. An angle of a rounded corner (dimension D8) may be included in a range of approximately 10 degrees to approximately 80 degrees. However, other values and ranges are within the scope of the present disclosure.

As further shown in the close-up view in FIG. 4A, the highest parts of the top surface of the source/drain contact structure 122 (e.g., the outer perimeter of the source/drain contact structure 122) may be spaced apart from the bottom of the ESL 128 in the z-direction by a distance corresponding to a dimension D9. In some implementations, the dimension D9 is included in a range of approximately 0 nanometers to approximately 7 nanometers. However, other values and ranges are within the scope of the present disclosure.

FIG. 4B illustrates an example implementation 404 of a source/drain contact structure 122 and a source/drain interconnect structure 134. As shown in FIG. 4B, the source/drain contact structure 122 and the source/drain interconnect structure 134 in the example implementation 404 are similar to the source/drain interconnect structure 134 in the example implementation illustrated in FIG. 1B.

However, in the example implementation 404, the source/drain interconnect structure 134 and the source/drain contact structure 122 may be partially offset from each other in the x-direction and/or in a y-direction in the semiconductor device 100. The partial offset may occur due to overlay misalignment when forming the recess 302. Thus, the bottom surface of source/drain interconnect structure 134 formed in the recess 302 may be laterally shifted relative to the top surface of the source/drain contact structure 122.

This may result in a portion 406 of the bottom surface of the source/drain interconnect structure 134 being in contact with the dielectric layer 108, and/or may result in a portion 408 of the top surface of the source/drain contact structure 122 being in contact with the ESL 128. In some implementations, a lateral size (dimension D10) of the portion 408 may be included in a range of approximately 0 nanometers to approximately 3 nanometers. However, other values and ranges are within the scope of the present disclosure. In some implementations, a lateral size (dimension D11) of the portion 406 may be included in a range of approximately 0 nanometers to approximately 3 nanometers. However, other values and ranges are within the scope of the present disclosure.

FIG. 4C illustrates an example implementation 410 of a source/drain contact structure 122 and a source/drain interconnect structure 134. As shown in FIG. 4B, the source/drain contact structure 122 and the source/drain interconnect structure 134 in the example implementation 410 are similar to the source/drain interconnect structure 134 in the example implementation illustrated in FIG. 1B.

However, in the example implementation 410, the interface between the bottom surface of the source/drain interconnect structure 134 and the top surface of the source/drain contact structure 122 may be uneven and/or non-uniform, and may have a non-uniform depth. This may result in various high spots and low spots in the interface between the bottom surface of the source/drain interconnect structure 134 and the top surface of the source/drain contact structure 122. A maximum low spot 412 may be a lowest point in the interface between the bottom surface of the source/drain interconnect structure 134 and the top surface of the source/drain contact structure 122, and a maximum high spot 414 may be a highest point in the interface between the bottom surface of the source/drain interconnect structure 134 and the top surface of the source/drain contact structure 122. The interface between the bottom surface of the source/drain interconnect structure 134 and the top surface of the source/drain contact structure 122 may have various intermediate spots 416, which may correspond to local high spots and/or local low spots.

In some implementations, a z-direction distance (dimension D12) between the maximum low spot 412 and the bottom of the ESL 128 may be included in a range of approximately 0 nanometers to approximately 5 nanometers. However, other values and ranges are within the scope of the present disclosure. In some implementations, a z-direction distance (dimension D13) between the maximum high spot 414 and the bottom of the ESL 128 may be included in a range of approximately 0 nanometers to approximately 3 nanometers. However, other values and ranges are within the scope of the present disclosure. In some implementations, a z-direction difference (dimension D14) between the dimension D12 and the dimension D13 may be included in a range of approximately 0 nanometers to approximately 2 nanometers.

In some implementations, a z-direction distance (dimension D15) between an intermediate spot 416 and the bottom of the ESL 128 may be less than the dimension D12 and greater than the dimension D13). In some implementations, a z-direction difference between the dimension D13 and the dimension D15 is indicated as a dimension D16.

FIG. 4D illustrates an example implementation 418 of a source/drain contact structure 122 and a source/drain interconnect structure 134. As shown in FIG. 4D, the source/drain contact structure 122 and the source/drain interconnect structure 134 in the example implementation 418 are similar to the source/drain interconnect structure 134 in the example implementation 410 illustrated in FIG. 4C. However, in the example implementation 418, the maximum low spot 412 and the maximum high spot 414 in the interface between the bottom surface of the source/drain interconnect structure 134 are located at opposing sides of the source/drain contact structure 122 and at opposing sides of the source/drain interconnect structure 134. The interface may transition between the maximum low spot 412 at a first side of the source/drain contact structure 122 and at a first side of the source/drain interconnect structure 134, to the maximum high spot 414 at a second (opposing) side of the source/drain contact structure 122 and at a second (opposing) side of the source/drain interconnect structure 134.

As indicated above, FIGS. 4A-4D are provided as examples. Other examples may differ from what is described with regard to FIGS. 4A-4D.

FIGS. 5A-5E are diagrams of example implementations of source/drain contact structures 122 and source/drain interconnect structures 134 for the semiconductor device 100 described herein. FIG. 5A illustrates an example implementation 500 of a source/drain contact structure 122 and a source/drain interconnect structure 134. FIG. 5B illustrates an example implementation 502 of a source/drain contact structure 122 and a source/drain interconnect structure 134. FIG. 5C illustrates an example implementation 504 of a source/drain contact structure 122 and a source/drain interconnect structure 134. FIG. 5D illustrates an example implementation 506 of a source/drain contact structure 122 and a source/drain interconnect structure 134. FIG. 5E illustrates an example implementation 508 of a source/drain contact structure 122 and a source/drain interconnect structure 134.

The example implementations 500-508 in FIGS. 5A-5E are respectively similar to the example implementations 100, 400, 404, 410, 418 of source/drain contact structures 122 and source/drain interconnect structure 134 in FIGS. 1B, 4A, 4B, 4C, and 4D. However, in the example implementations 500-508 in FIGS. 5A-5E, the top surfaces of the source/drain contact structures 122 are wider than the bottom surfaces of the source/drain interconnect structures 134. Thus, in the example implementations 500-508 in FIGS. 5A-5E, the top surfaces of the source/drain contact structures 122 extend laterally outward past one or more side of the bottom surfaces of the source/drain interconnect structures 134. This may reduce the likelihood of and/or the amount of lateral misalignment between the source/drain contact structures 122 and the source/drain interconnect structures 134.

As indicated above, FIGS. 5A-5E are provided as examples. Other examples may differ from what is described with regard to FIGS. 5A-5E.

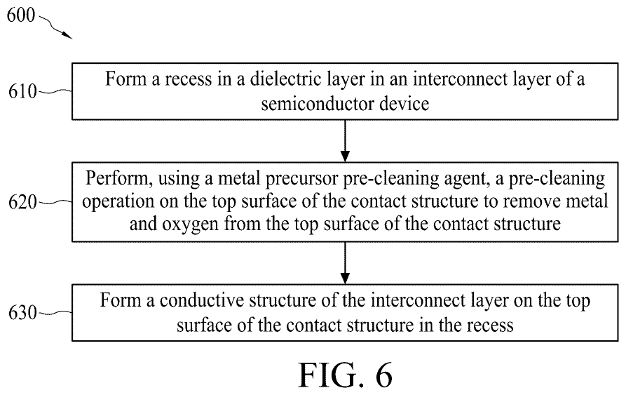

FIG. 6 is a flowchart of an example process 600 associated with forming a semiconductor device described herein. In some implementations, one or more process blocks of FIG. 6 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 6, process 600 may include forming a recess in a dielectric layer in an interconnect layer of a semiconductor device (block 610). For example, one or more semiconductor processing tools may be used to form a recess (e.g., a recess 302) in a dielectric layer (e.g., an ILD layer 126, an ESL 128) in an interconnect layer (e.g., an interconnect layer 104) of a semiconductor device (e.g., a semiconductor device 100), as described herein. In some implementations, a top surface of a contact structure (e.g., a source/drain contact structure 122) of the semiconductor device is exposed through the recess.

As further shown in FIG. 6, process 600 may include performing, using a metal precursor pre-cleaning agent, a pre-cleaning operation on the top surface of the contact structure (block 620). For example, one or more semiconductor processing tools may be used to perform, using a metal precursor pre-cleaning agent (e.g., a pre-cleaning agent 308), a pre-cleaning operation on the top surface of the contact structure, as described herein.

As further shown in FIG. 6, process 600 may include forming a conductive structure of the interconnect layer on the top surface of the contact structure in the recess (block 630). For example, one or more semiconductor processing tools may be used to form a conductive structure (e.g., a source/drain interconnect structure 134) of the interconnect layer on the top surface of the contact structure in the recess, as described herein.

Process 600 may include additional implementations, such as any single implementation or any combination of implementations described below and/or in connection with one or more other processes described elsewhere herein.

In a first implementation, performing the pre-cleaning operation includes performing a chemical soak where the metal precursor pre-cleaning agent remains on the top surface of the contact structure for a time duration.

In a second implementation, alone or in combination with the first implementation, the metal precursor pre-cleaning agent includes a halogen-containing metal precursor.

In a third implementation, alone or in combination with one or more of the first and second implementations, the metal precursor pre-cleaning agent includes a fluorine-containing metal precursor.

In a fourth implementation, alone or in combination with one or more of the first through third implementations, the metal precursor pre-cleaning agent includes a chlorine-containing metal precursor.

In a fifth implementation, alone or in combination with one or more of the first through fourth implementations, the metal precursor pre-cleaning agent includes a metal precursor of a material of the contact structure.

In a sixth implementation, alone or in combination with one or more of the first through fifth implementations, the metal precursor pre-cleaning agent includes a metal precursor of a material of the conductive structure.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

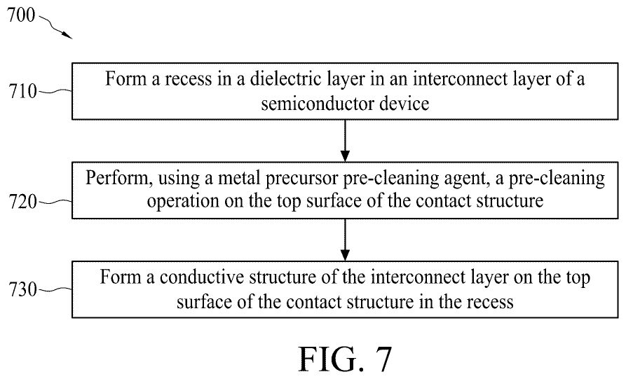

FIG. 7 is a flowchart of an example process 700 associated with forming a semiconductor device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a recess in a dielectric layer in an interconnect layer of a semiconductor device (block 710). For example, one or more semiconductor processing tools may be used to form a recess (e.g., a recess 302) in a dielectric layer (e.g., an ILD layer 126, an ESL 128) in an interconnect layer (e.g., an interconnect layer 104) of a semiconductor device (e.g., a semiconductor device 100), as described herein. In some implementations, the interconnect layer is located above a device layer (e.g., a device layer 102) of the semiconductor device. In some implementations, a top surface of a contact structure (e.g., a source/drain contact structure 122) of the semiconductor device is exposed through the recess.

As further shown in FIG. 7, process 700 may include performing, using a metal precursor pre-cleaning agent, a pre-cleaning operation on the top surface of the contact structure to remove metal and oxygen from the top surface of the contact structure (block 720). For example, one or more semiconductor processing tools may be used to perform, using a metal precursor pre-cleaning agent, a pre-cleaning operation on the top surface of the contact structure to remove metal and oxygen from the top surface of the contact structure, as described herein.

As further shown in FIG. 7, process 700 may include forming a conductive structure of the interconnect layer on the top surface of the contact structure in the recess (block 730). For example, one or more semiconductor processing tools may be used to form a conductive structure (e.g., a source/drain interconnect structure 134) of the interconnect layer on the top surface of the contact structure in the recess, as described herein. In some implementations, the pre-cleaning operation and forming the conductive structure are performed in a same processing chamber while maintaining a vacuum in the same processing chamber between the pre-cleaning operation and forming the conductive structure.

Process 700 may include additional implementations, such as any single implementation or any combination of implementations described below and/or in connection with one or more other processes described elsewhere herein.

In a first implementation, the metal precursor pre-cleaning agent includes a first metal precursor, and forming the conductive structure includes forming the conductive structure using a second metal precursor, where the first metal precursor and the second metal precursor comprise a same metal precursor.

In a second implementation, alone or in combination with the first implementation, the metal precursor pre-cleaning agent includes a first metal precursor, and forming the conductive structure includes forming the conductive structure using a second metal precursor, where the first metal precursor and the second metal precursor comprise different metal precursors.

In a third implementation, alone or in combination with one or more of the first and second implementations, the contact structure includes tungsten (W), and the metal precursor pre-cleaning agent includes at least one of tungsten fluoride (WFₓ), or chloride (WClₓ).

In a fourth implementation, alone or in combination with one or more of the first through third implementations, the contact structure includes molybdenum (Mo), and wherein the metal precursor pre-cleaning agent includes at least one of molybdenum fluoride (MoFₓ), or molybdenum chloride (MoClₓ).

In a fifth implementation, alone or in combination with one or more of the first through fourth implementations, performing the pre-cleaning operation includes performing the pre-cleaning operation at a temperature that is included in a range of approximately 200 degrees Celsius to approximately 450 degrees Celsius.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a pre-cleaning operation, using a metal-precursor, is performed to remove a metal-oxide layer from a top surface of a contact structure of a semiconductor device prior to forming a conductive structure of the semiconductor device on the contact structure. The use of the metal precursor as a pre-cleaning agent for the pre-cleaning operation enables native oxides to be fully removed (not just constituent parts such as oxygen) without causing the formation of pores in the top surface of the contact structure, which enables a low contact resistance to be achieved between the contact structure and the conductive structure.

As described in greater detail above, some implementations described herein provide a method. The method includes forming a recess in a dielectric layer in an interconnect layer of a semiconductor device, where a top surface of a contact structure of the semiconductor device is exposed through the recess. The method includes performing, using a metal precursor pre-cleaning agent, a pre-cleaning operation on the top surface of the contact structure. The method includes forming a conductive structure of the interconnect layer on the top surface of the contact structure in the recess.

As described in greater detail above, some implementations described herein provide a method. The method includes forming a recess in a dielectric layer in an interconnect layer of a semiconductor device, where the interconnect layer is located above a device layer of the semiconductor device, and where a top surface of a contact structure of the semiconductor device is exposed through the recess. The method includes performing, using a metal precursor pre-cleaning agent, a pre-cleaning operation on the top surface of the contact structure. The method includes forming a conductive structure of the interconnect layer on the top surface of the contact structure in the recess, where the pre-cleaning operation and forming the conductive structure are performed in a same processing chamber while maintaining a vacuum in the same processing chamber between the pre-cleaning operation and forming the conductive structure.

As described in greater detail above, some implementations described herein provide a semiconductor device. The semiconductor device includes a substrate layer. The semiconductor device includes an integrated circuit device at least one of in or on the substrate layer. The semiconductor device includes a contact structure in a first dielectric layer above the substrate layer and electrically coupled to the integrated circuit device, where the contact structure comprises a first metal material. The semiconductor device includes a conductive structure in a second dielectric layer above the first dielectric layer and in contact with the contact structure, where a bottom surface of the conductive structure is recessed in a top surface of the contact structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a recess in a dielectric layer in an interconnect layer of a semiconductor device,
wherein a top surface of a contact structure of the semiconductor device is exposed through the recess;
performing, using a metal precursor pre-cleaning agent, a pre-cleaning operation on the top surface of the contact structure; and
forming a conductive structure of the interconnect layer on the top surface of the contact structure in the recess.

2. The method of claim 1, wherein performing the pre-cleaning operation comprises:
performing a chemical soak where the metal precursor pre-cleaning agent remains on the top surface of the contact structure for a time duration.

3. The method of claim 1, wherein the metal precursor pre-cleaning agent comprises a halogen-containing metal precursor.

4. The method of claim 1, wherein the metal precursor pre-cleaning agent comprises a fluorine-containing metal precursor.

5. The method of claim 1, wherein the metal precursor pre-cleaning agent comprises a chlorine-containing metal precursor.

6. The method of claim 1, wherein the metal precursor pre-cleaning agent comprises a metal precursor of a material of the contact structure.

7. The method of claim 1, wherein the metal precursor pre-cleaning agent comprises a metal precursor of a material of the conductive structure.

8. A method, comprising:
forming a recess in a dielectric layer in an interconnect layer of a semiconductor device,
wherein the interconnect layer is located above a device layer of the semiconductor device, and
wherein a top surface of a contact structure of the semiconductor device is exposed through the recess;
performing, using a metal precursor pre-cleaning agent, a pre-cleaning operation on the top surface of the contact structure to remove metal and oxygen from the top surface of the contact structure; and
forming a conductive structure of the interconnect layer on the top surface of the contact structure in the recess,
wherein the pre-cleaning operation and forming the conductive structure are performed in a same processing chamber while maintaining a vacuum in the same processing chamber between the pre-cleaning operation and forming the conductive structure.

9. The method of claim 8, wherein the metal precursor pre-cleaning agent comprises a first metal precursor;
wherein forming the conductive structure comprises forming the conductive structure using a second metal precursor; and
wherein the first metal precursor and the second metal precursor comprise a same metal precursor.

10. The method of claim 8, wherein the metal precursor pre-cleaning agent comprises a first metal precursor;
wherein forming the conductive structure comprises forming the conductive structure using a second metal precursor; and
wherein the first metal precursor and the second metal precursor comprise different metal precursors.

11. The method of claim 8, wherein the contact structure comprises tungsten (W); and
wherein the metal precursor pre-cleaning agent comprises at least one of:
tungsten fluoride (WFₓ), or
tungsten chloride (WClₓ).

12. The method of claim 8, wherein the contact structure comprises molybdenum (Mo); and
wherein the metal precursor pre-cleaning agent comprises at least one of:
molybdenum fluoride (MoFₓ), or
molybdenum chloride (MoClₓ).

13. The method of claim 8, wherein performing the pre-cleaning operation comprises performing the pre-cleaning operation at a temperature that is included in a range of approximately 200 degrees Celsius to approximately 450 degrees Celsius.

14. A semiconductor device, comprising:
a substrate layer;
an integrated circuit device at least one of in or on the substrate layer;
a contact structure in a first dielectric layer above the substrate layer and electrically coupled to the integrated circuit device,
wherein the contact structure comprises a first metal material; and
a conductive structure in a second dielectric layer above the first dielectric layer and in contact with the contact structure,
wherein a bottom surface of the conductive structure is recessed in a top surface of the contact structure.

15. The semiconductor device of claim 14, wherein a depth of a recess in the top surface of the contact structure, in which the conductive structure is recessed, is included in a range of approximately 0.5 nanometers to approximately 5 nanometers.

16. The semiconductor device of claim 14, wherein the conductive structure is laterally offset from the contact structure such that a portion of the bottom surface of the conductive structure is in contact with the first dielectric layer.

17. The semiconductor device of claim 16, wherein a portion of the top surface of the contact structure is in contact with a third dielectric layer vertically between the first dielectric layer and the second dielectric layer.

18. The semiconductor device of claim 14, wherein a lateral width of the top surface of the contact structure is greater than a lateral width of the bottom surface of the conductive structure; and
wherein a recess in the top surface of the contact structure, in which the conductive structure is recessed, encompasses only a portion of the top surface of the contact structure.

19. The semiconductor device of claim 14, wherein a lateral width of a first portion of the conductive structure that is recessed in the top surface of the contact structure is greater than a lateral width of a second portion of the conductive structure above the top surface of the contact structure.

20. The semiconductor device of claim 14, wherein the bottom surface of the conductive structure is recessed to a non-uniform depth across the top surface of the contact structure.
